(19) United States
(12) Patent Application Publication
(10) Pub. No.: US 2024/0196592 A1
(43) Pub. Date: Jun. 13, 2024

(54) SEMICONDUCTOR DEVICE AND METHOD FOR FABRICATING THE SAME

(71) Applicant: SK hynix Inc., Gyeonggi-do (KR)

(72) Inventor: Seung Hwan KIM, Gyeonggi-do (KR)

(21) Appl. No.: 18/193,643

(22) Filed: Mar. 31, 2023

(30) Foreign Application Priority Data
Aug. 5, 2022 (KR) 10-2022-0098031

(51) Int. Cl. H10B 12/00

(52) U.S. Cl. CPC H10B 12/30; H10B 12/03; H10B 12/05

(57) ABSTRACT

A semiconductor device includes a lower structure; a plurality of horizontal conductive layers that are oriented horizontally in a direction parallel to a surface of the lower structure; a vertical conductive line commonly coupled to first-side ends of the horizontal conductive layers and extending in a direction perpendicular to the surface of the lower structure; and a plurality of reservoir capacitors respectively coupled to second-side ends of the horizontal conductive layers and vertically stacked over the lower structure.

### CROSS-REFERENCE TO RELATED APPLICATIONS

The present application claims priority of Korean Patent Application No. 10-2022-0098031, filed on Aug. 5, 2022, which is incorporated herein by reference in its entirety.

### BACKGROUND

### 1. Field

Exemplary embodiments of the present invention relate to a semiconductor device and, more particularly, to a semiconductor device of a three-dimensional structure, and a method for fabricating the same.

### 2. Description of the Related Art

The size of a memory cell is being decreased continuously in order to increase the net die of a memory device. However, as the size of the memory cell is miniaturized, it is required to reduce the parasitic capacitance Cb while increasing the capacitance of the memory cell. However, it has become increasingly more difficult to continue increasing the net die of two-dimensional memory devices due to the structural and space requirements of a memory cell.

As a solution, rather recently, three-dimensional (3D) semiconductor memory devices including memory cells that are arranged in three dimensional arrangements have been proposed.

### SUMMARY

Various embodiments of the present invention are directed to a highly integrated semiconductor device, and a method for fabricating the semiconductor device.

In accordance with an embodiment of the present invention, a semiconductor device includes: a lower structure; a plurality of horizontal conductive layers that are oriented horizontally in a direction parallel to a surface of the lower structure; a vertical conductive line commonly coupled to first-side ends of the horizontal conductive layers and extending in a direction perpendicular to the surface of the lower structure; and a plurality of reservoir capacitors respectively coupled to second-side ends of the horizontal conductive layers and vertically stacked over the lower structure. The semiconductor device further includes: a memory cell array which is disposed over the lower structure and arranged horizontally from the reservoir capacitors. The memory cell array further includes: horizontal active layers extending in a direction parallel to the surface of the lower structure; a bit line commonly coupled to first sides of the horizontal active layers and extending in a direction perpendicular to the surface of the lower structure; and word lines respectively overlapping with the horizontal active layers and extending in a direction crossing the horizontal active layers, and the cell capacitors are respectively coupled to second sides of the horizontal active layers.

In accordance with another embodiment of the present invention, a semiconductor device includes: a peripheral circuit portion; a three-dimensional array of memory cells disposed at a higher level than the peripheral circuit portion and including a vertical bit line, a horizontal word line, and a cell capacitor between the vertical bit line and the horizontal word line; and a reservoir capacitor array disposed horizontally from the three-dimensional array of memory cells at a higher level than the peripheral circuit portion, and including reservoir capacitors disposed at the same lateral level as a lateral level of the cell capacitors, wherein the reservoir capacitor array comprises: a plurality of horizontal conductive lines oriented horizontally in a direction parallel to a surface of the peripheral circuit portion; a vertical conductive line commonly coupled to first-side ends of the horizontal conductive lines and extending in a direction perpendicular to the surface of the peripheral circuit portion; and a plurality of reservoir capacitors respectively coupled to second-side ends of the horizontal conductive lines and stacked vertically over the peripheral circuit portion. The peripheral circuit portion includes: a sense amplifier coupled to the vertical bit line; a sub-word line driver coupled to the horizontal word line; and a reservoir capacitor control circuit coupled to the reservoir capacitors. The vertical conductive line includes: a pillar portion oriented vertically in a direction perpendicular to the surface of the peripheral circuit portion; and extended portions which extend horizontally from the pillar portion. The horizontal conductive lines include a semiconductor material, an oxide semiconductor material, a doped semiconductor material, a metal or metal-based material, or a combination thereof. The vertical conductive line includes a silicon-based material, a metal or metal-based material, or a combination thereof. The semiconductor device further comprising: a first doped polysilicon layer disposed between the horizontal conductive lines and the vertical conductive line and surrounding an outer wall of the vertical conductive line; and a second doped polysilicon layer disposed between the horizontal conductive lines and the reservoir capacitors and oriented vertically.

In accordance with another embodiment of the present invention, a method for fabricating a semiconductor device includes: forming a memory cell array including a three-dimensional array of cell capacitors over a lower structure; and forming a reservoir capacitor array including a three-dimensional array of reservoir capacitors that are disposed horizontally from the memory cell array over the lower structure, wherein the forming of the reservoir capacitor array comprises: forming a plurality of horizontal conductive lines that are oriented horizontally in a direction parallel to a surface of the lower structure; forming a vertical conductive line that is commonly coupled to first-side ends of the horizontal conductive lines and extending in a direction perpendicular to the surface of the lower structure; and forming the reservoir capacitors that are respectively coupled to second-side ends of the horizontal conductive lines and stacked vertically over the lower structure. The reservoir capacitors are formed to have the same structure as a structure of the cell capacitors, and the reservoir capacitors are formed at the same level as a level of the cell capacitors and have the same size as a size of the cell capacitors. The vertical conductive line includes: a pillar portion oriented vertically in a direction perpendicular to the surface of the lower structure; and extended portions which extend horizontally from the pillar portion. The horizontal conductive lines include a semiconductor material, an oxide semiconductor material, a doped semiconductor material, a metal or metal-based material, or a combination thereof. The vertical conductive line includes a silicon-based material, a metal or metal-based material, or a combination thereof. The method further includes: forming a first doped polysilicon layer which is disposed between the horizontal conductive lines and the vertical conductive line and surrounding an outer wall of the vertical conductive line; and forming a second doped polysilicon layer which is disposed between the horizontal conductive lines and the reservoir capacitors and oriented vertically.

These and other features and advantages of the present invention will become apparent from the following detailed description in conjunction with the following claims.

### BRIEF DESCRIPTION OF THE DRAWINGS

FIG. 1 is a simplified schematic diagram illustrating a semiconductor device in accordance with an embodiment of the present invention.

FIG. 2 is a cross-sectional view of the semiconductor device of FIG. 1 taken along a line A-A′ shown in FIG. 1.

FIG. 3 is a plan view of the semiconductor device of FIG. 1 taken along a line B-B′ shown in FIG. 1.

FIGS. 4 and 5 illustrate a semiconductor device in accordance with another embodiment of the present invention.

FIGS. 6A and 6B illustrate a semiconductor device in accordance with yet another embodiment of the present invention.

FIGS. 7 to 21 are cross-sectional views illustrating a method for fabricating a semiconductor device in accordance with another embodiment of the present invention.

FIGS. 22 to 30 are cross-sectional views illustrating a method for forming a memory cell array.

FIG. 31 is a schematic cross-sectional view illustrating a semiconductor device in accordance with another embodiment of the present invention.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

An embodiment of the present invention as described below can increase a memory cell density and reduce a parasitic capacitance by vertically stacking memory cells.

Semiconductor devices such as a Dynamic Random Access Memory (DRAM) may include not only a memory cell array but also capacitors for stable power supply or stabilization of transferred signals as well as. In particular, in order to stabilize a voltage from such factors as noise, a reservoir capacitor having a large capacitance may be formed in a spare space of a peripheral circuit.

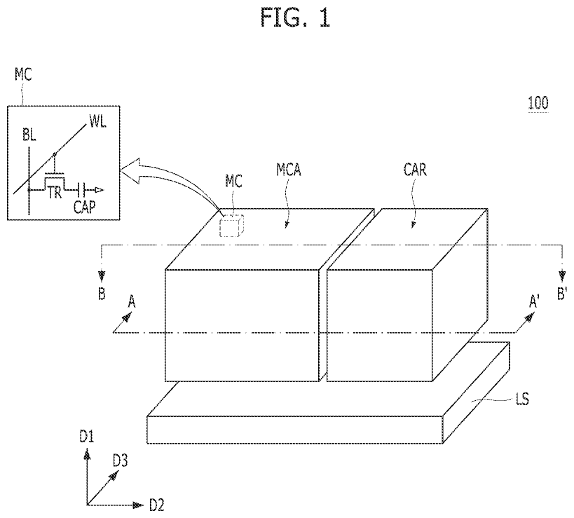

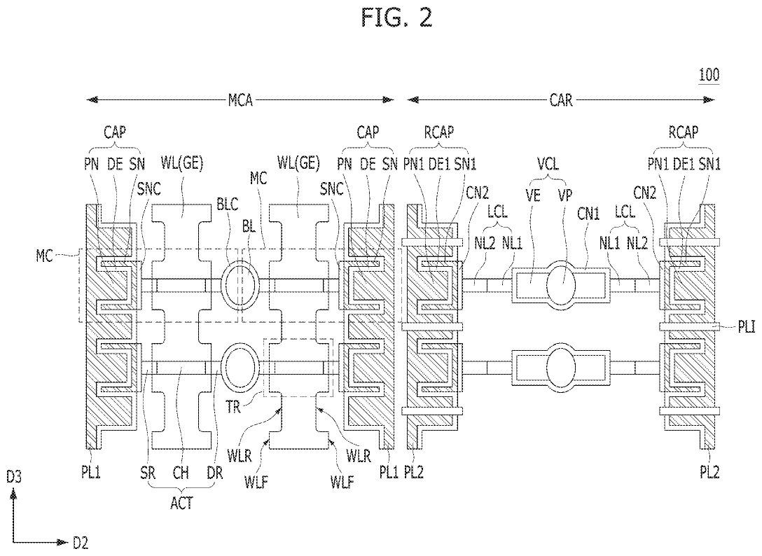

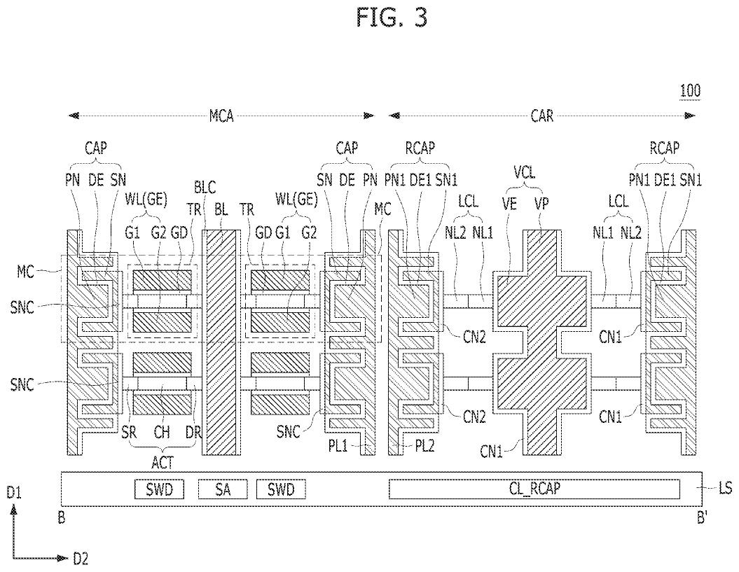

FIG. 1 is a simplified schematic diagram illustrating a semiconductor device in accordance with an embodiment of the present invention. FIG. 2 is a cross-sectional view of the semiconductor device of FIG. 1 which is taken along a line A-A′ shown in FIG. 1. FIG. 3 is a plan view taken along a line B-B′ shown in FIG. 1.

Referring to FIGS. 1 to 3, the semiconductor device 100 may include a lower structure LS, a memory cell array MCA, and a reservoir capacitor array CAR. The memory cell array MCA and the reservoir capacitor array CAR may be disposed over the lower structure LS. The memory cell array MCA and the reservoir capacitor array CAR may each be vertically disposed in a first direction D1 over the lower structure LS. The memory cell array MCA and the reservoir capacitor array CAR may be disposed horizontally to each other in a second direction D2.

The memory cell array MCA may include a plurality of memory cells MC arranged in a three dimensional arrangement. Each memory cell MC may include a switching element TR and a data storage element CAP coupled to each other. The data storage element CAP may be coupled to bit line BL through the switching element TR. The switching element TR may be a field effect transistor (FET). The data storage element CAP may be a capacitor. Hereinafter, the switching element TR may be simply referred to as a transistor, and the data storage element CAP may be simply referred to as a cell capacitor or capacitor. The transistor TR and the capacitor CAP may be disposed between a word line WL and a bit line BL which disposed cross each other.

A transistor TR of each memory cell MC may include a horizontal active layer ACT. The horizontal active layer ACT may be coupled to the cell capacitor CAP and the bit line BL. The horizontal active layer ACT may include a first source/drain region DR, a second source/drain region SR, and a channel CH disposed horizontally between the first source/drain region DR and the second source/drain region SR. The transistor TR may further include a word line WL or a gate electrode GE overlapping with the channel CH. The gate electrode GE may be a portion of the word line WL, the first source/drain region DR may be coupled to the bit line BL, and the second source/drain region SR may be coupled to the cell capacitor CAP. As described above, one side of the horizontal active layer ACT may be coupled to the bit line BL, and an opposite side of the horizontal active layer ACT may be coupled to the cell capacitor CAP. The horizontal active layer ACT may be referred to as a horizontal active layer or a thin-body active layer ACT.

Each memory cell MC may include a single transistor TR and a single cell capacitor CAP. This configuration is referred to herein also as a ‘1T1C cell’. The single cell capacitor CAP of the 1T1C cell may store data. The single transistor TR may serve as an access device for accessing to read data from or write data into the single cell capacitor CAP. According to another embodiment of the present invention, the single transistor TR may serve as a selective device.

The memory cell array MCA may include a plurality of bit lines BL, a plurality of transistors TR, and a plurality of cell capacitors CAP. The cell capacitors CAP may be vertically stacked in the first direction D1 and share a first plate line PL1.

The reservoir capacitor array CAR may include a plurality of reservoir capacitors RCAP. The reservoir capacitors RCAP may be vertically stacked in the first direction D1. The reservoir capacitors RCAP that are stacked in the first direction D1 may share a second plate line PL2. The reservoir capacitors RCAP disposed adjacent to each other in the third direction D3 may be separated from each other by a plate line isolation layer PLI.

The plate nodes PN of the cell capacitors CAP may be coupled to each other and to the first plate line PL1. The plate nodes PN1 of the reservoir capacitors RCAP may be coupled to each other and to the second plate line PL2.

The memory cell array MCA may include a three-dimensional (3D) array of memory cells MC, and may also include a 3D array of cell capacitors CAP. For example, in the memory cell array MCA, a plurality of memory cells MC may be stacked in a first direction D1, and a plurality of memory cells MC may be arranged horizontally in the second and third directions D2 and D3.

Also, in the reservoir capacitor array CAR, a plurality of reservoir capacitors RCAP may be stacked in the first direction D1. Also, a plurality of reservoir capacitors RCAP may be arranged horizontally in the second and third directions D2 and D3. Thus, the reservoir capacitor array CAR may include a three-dimensional array of reservoir capacitors RCAP.

The reservoir capacitors RCAP may have substantially the same structure as those of the cell capacitors CAP. The reservoir capacitors RCAP may be formed at the same level as the level of the cell capacitors CAP and have the same size. The reservoir capacitors RCAP and the cell capacitors CAP may have substantially the same capacitance.

The memory cell array MCA may be a first column array including cell capacitors CAP that are stacked in the first direction D1. The cell capacitors CAP of the first column array may be referred to as a cell capacitor array. The reservoir capacitor array RCAP may be a second column array including reservoir capacitors RCAP that are stacked in the first direction D1. In the first and second column arrays, each of the cell capacitors CAP and the reservoir capacitors RCAP may include storage nodes SN that are separated from each other. Each of the cell capacitors CAP and the reservoir capacitors RCAP may include plate nodes PN and PN1 coupled to each other. The first plate line PL1 and the second plate line PL2 may be separated from each other.

Each transistor TR may include a horizontal active layer ACT and a word line WL. The word line WL may include first and second word lines G1 and G2 facing each other with the horizontal active layer ACT interposed therebetween. Gate dielectric layer GD may be disposed between the horizontal active layer ACT and the word line WL. The gate dielectric layer GD may be formed between the first word line G1 and the horizontal active layer ACT and also between the second word line G2 and the horizontal active layer ACT. Each of the cell capacitors CAP and the reservoir capacitors RCAP may include a storage node SN, a first dielectric layer DE, and a first plate node PN.

The bit line BL of the memory cell array MCA may have a pillar shape extending in the first direction D1. The horizontal active layer ACT may have a bar shape extending in the second direction D2 that intersects with the first direction D1. The word line WL may have a line shape extending in the third direction D3 that intersects with the first and second directions D1 and D2.

The bit line BL may be vertically oriented in the first direction D1. The bit line BL may be referred to as a vertically oriented bit line or a pillar-type bit line. The bit line BL may include a conductive material. The bit line BL may include a silicon-based material, a metal or metal-based material, or a combination thereof. The bit line BL may include silicon, a metal, a metal nitride, a metal silicide, or a combination thereof. The bit line BL may include polysilicon, titanium nitride, tungsten, or a combination thereof. For example, the bit line BL may include polysilicon or titanium nitride (TiN) which is doped with an N-type impurity. The bit line BL may include a TiN/W stack including titanium nitride and tungsten over the titanium nitride.

A bit line contact node BLC surrounding the outer wall of the bit line BL may be formed. The bit line contact node BLC may be coupled to the first source/drain region DR. The bit line contact node BLC may include a conductive material. The bit line contact node BLC may include a silicon-based material, a metal or metal-based material, or a combination thereof. The bit line contact node BLC may include silicon, a metal, a metal nitride, a metal silicide, or a combination thereof. The bit line contact node BLC may include polysilicon, titanium nitride, tungsten, or a combination thereof. For example, the bit line contact node BLC may include N-type doped polysilicon or titanium nitride (TIN). For example, in an embodiment, the bit line BL may include a TiN/W stack including titanium nitride and tungsten on the titanium nitride, and the bit line contact node BLC may include N-type doped polysilicon.

The word line WL may extend along its length in the third direction D3. The horizontal active layer ACT may extend along its length in the second direction D2. The horizontal active layer ACT may be arranged horizontally in the second direction D2 from the bit line BL. The word line WL may include a pair of word lines, that is, first and second word lines G1 and G2. The first and second word lines G1 and G2 may face each other in the first direction D1 with the horizontal active layer ACT interposed therebetween. A gate dielectric layer GD may be formed on an upper surface and a lower surface of the horizontal active layer ACT.

In the word line WL, the first and second word lines G1 and G2 may have the same potential. For example, the first and second word lines G1 and G2 may form a pair and the same word line driving voltage may be applied to the pair of the first and second word lines G1 and G2. As described above, the semiconductor device 100 according to the embodiment of the present invention may have a double word line structure in which the first and second word lines G1 and G2 are disposed adjacent to one horizontal active layer ACT. The double word line structure may also be referred to as a double gate structure.

The horizontal active layer ACT may include a semiconductor material. The horizontal active layer ACT may include a silicon-containing layer or a silicon germanium-containing layer. For example, the horizontal active layer ACT may include silicon, monocrystalline silicon, doped polysilicon, undoped polysilicon, amorphous silicon, silicon germanium, or a combination thereof. According to another embodiment of the present invention, the horizontal active layer ACT may include a nano-wire or a nano sheet, and the nano-wire and the nano-sheet may be formed of a semiconductor material. According to another embodiment of the present invention, the horizontal active layer ACT may include an oxide semiconductor material. The first source/drain region DR and the second source/drain region SR may be formed in the horizontal active layer ACT by ion implantation of an impurity or plasma doping.

From a top view, the word line WL may include notch-shaped sidewalls facing each other. Each of the notch-shaped sidewalls may include flat surfaces WLF and recessed surfaces WLR. The flat surfaces WLF and the recessed surfaces WLR may be alternately repeated in the third direction D3. The flat surfaces WLF may be flat sidewalls, and the recessed surfaces WLR may be recessed sidewalls. The flat surfaces WLF may face each other in the second direction D2. The recessed surfaces WLR may face each other in the second direction D2. The first and second word lines G1 and G2 may include notch-shaped sidewalls including a plurality of flat surfaces WLF and a plurality of recessed surfaces WLR.

The horizontal active layer ACT may have a thickness which is smaller than the thickness of each of the first and second word lines G1 and G2. For example, the vertical thickness of the horizontal active layer ACT in the first direction D1 may be smaller than the vertical thickness of each of the first and second word lines G1 and G2 in the first direction D1. The thin horizontal active layer ACT may be referred to as a thin-body horizontal active layer.

The gate dielectric layer GD may include silicon oxide, silicon nitride, a metal oxide, a metal oxynitride, a metal silicate, a high-k material, a ferroelectric material, an anti-ferroelectric material or a combination thereof. The gate dielectric layer GD may include SiO₂, Si₃N₄, HfO₂, Al₂O₃, ZrO₂, AION, HfON, HfSIO, HfSION, or HfZrO.

The first and second word lines G1 and G2 of the word line WL may include a metal or metal-based material, a semiconductor material, or a combination thereof. The first and second word lines G1 and G2 of the word line WL may include titanium nitride, tungsten, polysilicon, or a combination thereof. For example, the first and second word lines G1 and G2 of the word line WL may include a TiN/W stack in which titanium nitride and tungsten are sequentially stacked. The first and second word lines G1 and G2 of the word line WL may include a high work function material, a low work function material, or a combination thereof. The low work function material may have a low work function of approximately 4.5 eV or less, and the high work function material may have a high work function of approximately 4.5 eV or more. For example, the low work function material may include N-type doped polysilicon, and the high work function material may include tungsten, titanium nitride, or a combination thereof. According to another embodiment of the present invention, the first and second word lines G1 and G2 of the word line WL may have a dual work function structure in which a low work function material and a high work function material are combined.

The capacitor CAP may be disposed horizontally from the transistor TR in the second direction D2. The cell capacitor CAP may include a first storage node SN extending horizontally from the horizontal active layer ACT in the second direction D2. The cell capacitor CAP may further include a first dielectric layer DE and a first plate node PN over the first storage node SN. The first storage node SN, the first dielectric layer DE, and the first plate node PN may be horizontally arranged in the second direction D2. The first storage node SN may have a horizontally oriented cylinder-shape. The first dielectric layer DE may conformally cover the cylindrical inner wall and the cylindrical outer wall of the first storage node SN. The first plate node PN may have a shape extending to the cylindrical inner wall and the cylindrical outer wall of the first storage node SN over the first dielectric layer DE. The first storage node SN may be electrically connected to the horizontal active layer ACT.

The first storage node SN may have a three-dimensional structure, and the first storage node SN of the three-dimensional structure may have a lateral three-dimensional structure which is oriented in the second direction D2. As an example of the three-dimensional structure, the first storage node SN may have a cylindrical shape. According to another embodiment of the present invention, the first storage node SN may have a pillar shape or a pylinder shape. The pylinder shape may refer to a structure in which a pillar shape and a cylinder shape are merged.

The first storage node SN and the first plate node PN may include a metal, a noble metal, a metal nitride, a conductive metal oxide, a conductive noble metal oxide, a metal carbide, a metal silicide, or a combination thereof. For example, the first storage node SN and the first plate node PN may include titanium (Ti), titanium nitride (TiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, or a tungsten nitride/tungsten (WN/W) stack. The first plate node PN may include a combination of a metal or metal-based material and a silicon-based material. For example, the first plate node PN may be a stack of titanium nitride/silicon germanium/tungsten nitride (TiN/SiGe/WN). In the titanium nitride/silicon germanium/tungsten nitride (TiN/SiGe/WN) stack, silicon germanium may be a gap-fill material filling the cylindrical inside of the first storage node SN over the titanium nitride, and titanium nitride (TiN) may serve as a first plate node PN of a capacitor CAP, and tungsten nitride may be a low-resistance material.

The first dielectric layer DE may include silicon oxide, silicon nitride, a high-k material, or a combination thereof. The high-k material may have a higher dielectric constant than silicon oxide. Silicon oxide (SiO₂) may have a dielectric constant of approximately 3.9, and the first dielectric layer DE may include a high-k material having a dielectric constant of approximately 4 or more. The high-k material may have a dielectric constant of approximately 20 or more. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). According to another embodiment of the present invention, the first dielectric layer DE may be formed of a composite layer including two or more layers of the aforementioned high-k materials.

The first dielectric layer DE may be formed of zirconium (Zr)-based oxide. The first dielectric layer DE may have a stack structure including at least zirconium oxide (ZrO₂). The first dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked over zirconium oxide (ZrO₂). The ZAZ stack may have a structure in which zirconium oxide (ZrO₂), aluminum oxide (Al₂O₃), and zirconium oxide (ZrO₂) are sequentially stacked. The ZA stack and the ZAZ stack may be referred to as a zirconium oxide (ZrO₂)-based layer. According to another embodiment of the present invention, the first dielectric layer DE may be formed of hafnium (Hf)-based oxide. The first dielectric layer DE may have a stack structure including at least hafnium oxide (HfO₂). The first dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked over hafnium oxide (HfO₂). The HAH stack may have a structure in which hafnium oxide (HfO₂), aluminum oxide (Al₂O₃), and hafnium oxide (HfO₂) are sequentially stacked. The HA stack and the HAH stack may be referred to as a hafnium oxide (HfO₂)-based layer. In the ZA stack, ZAZ stack, HA stack, and HAH stack, aluminum oxide (Al₂O₃) may have a greater bandgap energy (which will be, hereinafter, simply referred to as bandgap) than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the first dielectric layer DE may include a stack of a high-k material and a high-bandgap material having a greater bandgap than the high-k material. The first dielectric layer DE may include silicon oxide (SiO₂) as a high bandgap material other than aluminum oxide (Al₂O₃). Since the first dielectric layer DE includes a high bandgap material, leakage current may be suppressed. The high-bandgap material may be thinner than the high-k material. According to another embodiment of the present invention, the first dielectric layer DE may include a laminated structure in which a high-k material and a high-bandgap material are alternately stacked. For example, the first dielectric layer DE may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA (HfO₂/Al₂O₃/HfO₂/Al₂O₃) stack, or a HAHAH (HfO₂/Al₂O₃/HfO₂/Al₂O₃/HfO₂) stack. In the above laminated structure, aluminum oxide (Al₂O₃) may be thinner than zirconium oxide (ZrO₂) and hafnium oxide (HfO₂).

According to another embodiment of the present invention, the first dielectric layer DE may include a stack structure, a laminated structure, or a mixed structure including zirconium oxide, hafnium oxide, and aluminum oxide.

According to another embodiment of the present invention, the first dielectric layer DE may include a ferroelectric material or an antiferroelectric material. The ferroelectric material may include HfZrO, HfSiO, or a combination thereof. Each of the cell capacitors CAP and the reservoir capacitors RCAP may include a ferroelectric capacitor.

According to another embodiment of the present invention, an interface control layer for improving leakage current may be further formed between the first storage node SN and the first dielectric layer DE. The interface control layer may include titanium oxide (TiO₂), niobium oxide, or niobium nitride. The interface control layer may also be formed between the first plate node PN and the first dielectric layer DE.

The capacitor CAP may include a metal-insulator-metal (MIM) capacitor. The first storage node SN and the first plate node PN may include a metal or metal-based material.

A storage contact node SNC may be formed between the first storage node SN and the second source/drain region SR. The storage contact node SNC may be coupled to the second source/drain region SR. The storage contact node SNC may include a conductive material. The storage contact node SNC may include a silicon-based material, a metal or metal-based material, or a combination thereof. The storage contact node SNC may include silicon, a metal, a metal nitride, a metal silicide, or a combination thereof. The storage contact node SNC may include polysilicon, titanium nitride, tungsten, or a combination thereof. For example, the storage contact node SNC may include N-type doped polysilicon or titanium nitride (TiN).

The first source/drain region DR may include impurities diffused from the bit line contact node BLC. The second source/drain region SR may include impurities diffused from the storage contact node SNC.

The reservoir capacitor array CAR may include horizontal conductive lines LCL coupled to the reservoir capacitors RCAP. The memory cell array MCA may include word lines WL extending in a direction crossing each of the horizontal active layers ACT. The reservoir capacitor array CAR may not have a material crossing the horizontal conductive lines LCL. For example, the reservoir capacitor array CAR may be word line-free or transistor-free.

The reservoir capacitors RCAP may be respectively coupled to first sides of the horizontal conductive lines LCL. Second sides of the horizontal conductive lines LCL may be coupled to the vertical conductive line VCL. The vertical conductive line VCL may extend in the first direction D1. The vertical conductive line VCL may include a pillar portion VP and a plurality of extended portions VE. A first contact node CN1 may be formed between the vertical conductive line VCL and the horizontal conductive line LCL. A second contact node CN2 may be formed between the horizontal conductive line LCL and the reservoir capacitors RCAP.

The horizontal conductive lines LCL may include a semiconductor material. The horizontal conductive lines LCL may include a silicon-containing layer or a silicon germanium-containing layer. For example, the horizontal conductive lines LCL may include silicon, monocrystalline silicon, doped polysilicon, undoped polysilicon, amorphous silicon, silicon germanium, or a combination thereof. According to another embodiment of the present invention, the horizontal conductive lines LCL may include a nano-wire or a nano sheet, and the nano-wire and the nano-sheet may be formed of a semiconductor material. According to another embodiment of the present invention, the horizontal conductive lines LCL may include an oxide semiconductor material.

Each of the horizontal conductive lines LCL may include first and second horizontal portions NL1 and horizontal portion NL2. The first horizontal portion NL1 may be coupled to the vertical conductive line VCL through the first contact node CN1. The second horizontal portion NL2 may be coupled to the reservoir capacitors RCAP through the second contact node CN2. The first and second horizontal portions NL1 and horizontal portion NL2 may include a conductive material.

The first and second horizontal portions NL1 and horizontal portion NL2 may include a semiconductor material, a semiconductor material doped with an impurity, or an oxide semiconductor material. For example, the first and second horizontal portions NL1 and NL2 may be doped with impurities of the same conductivity type. The first and second horizontal portions NL1 and NL2 may be doped with an N-type impurity or a P-type impurity. The first and second horizontal portions NL1 and NL2 may include at least one impurity selected among arsenic (As), phosphorus (P), boron (B), indium (In), and combinations thereof. The first and second horizontal portions NL1 and NL2 may be formed of a silicon material doped with an N-type impurity. The first and second horizontal portions NL1 and NL2 may be polysilicon doped with an N-type impurity.

According to another embodiment of the present invention, the first and second horizontal portions NL1 and NL2 may include a metal or metal-based material. For example, the first and second horizontal portions NL1 and NL2 may include a metal, a metal nitride, a metal silicide, or a combination thereof.

According to another embodiment of the present invention, the first and second horizontal portions NL1 and NL2 may include a monocrystalline silicon material or a doped monocrystalline silicon material.

The first and second horizontal portions NL1 and NL2 may extend in the second direction D2 and may contact each other.

The vertical conductive line VCL may be vertically oriented in the first direction D1. The vertical conductive line VCL may be referred to as a vertically oriented conductive line or a pillar-type conductive line. The pillar portion VP of the vertical conductive line VCL may be vertically oriented in the first direction D1, and the extended portions VE may extend from the pillar portion VP in the second direction D2. The vertical conductive line VCL may include a conductive material. The vertical conductive line VCL may include a silicon-based material, a metal or metal-based material, or a combination thereof. The vertical conductive line VCL may include silicon, a metal, a metal nitride, a metal silicide, or a combination thereof. The vertical conductive line VCL may include polysilicon, titanium nitride, tungsten, or a combination thereof. For example, the vertical conductive line VCL may include polysilicon or titanium nitride (TiN) which doped with an N-type impurity. The vertical conductive line VCL may include a TiN/W stack including titanium nitride and tungsten over the titanium nitride. The pillar portion VP and the extended portion VE of the vertical conductive line VCL may be formed of the same material and may have an integrated structure.

The first contact node CN1 may surround the outer wall of the vertical conductive line VCL. The first contact node CN1 may be coupled to the first horizontal portion NL1. The first contact node CN1 may include a conductive material. The first contact node CN1 may include a silicon-based material, a metal or metal-based material, or a combination thereof. The first contact node CN1 may include silicon, a metal, a metal nitride, a metal silicide, or a combination thereof. The first contact node CN1 may include polysilicon, titanium nitride, tungsten, or a combination thereof. For example, the first contact node CN1 may include N-type doped polysilicon or titanium nitride (TIN). The vertical conductive line VCL may include a TiN/W stack including titanium nitride and tungsten over the titanium nitride, and the first contact node CN1 may include N-type doped polysilicon.

The reservoir capacitor RCAP may be formed of the same structure and the same material as those of the cell capacitor CAP.

The reservoir capacitor RCAP may be disposed horizontally in the second direction D2 from the horizontal conductive line LCL. The reservoir capacitor RCAP may include a second storage node SN1 extending horizontally from the horizontal conductive line LCL in the second direction D2. The reservoir capacitor RCAP may further include a second dielectric layer DE1 and a second plate node PN1 over the second storage node SN1. The first storage node SN of the cell capacitor CAP and the second storage node SN1 of the reservoir capacitor RCAP may be formed of the same structure and the same material. The first dielectric layer DE of the cell capacitor CAP and the second dielectric layer DE1 of the reservoir capacitor RCAP may be formed of the same structure and the same material. The first plate node PN of the cell capacitor CAP and the second plate node PN1 of the reservoir capacitor RCAP may be formed of the same structure and the same material.

The second storage node SN1, the second dielectric layer DE1, and the second plate node PN1 may be arranged horizontally in the second direction D2. The second storage node SN1 may have a horizontally oriented cylinder-shape. The second dielectric layer DE1 may conformally cover the cylindrical inner wall and the cylindrical outer wall of the second storage node SN1. The second plate node PN1 may have a shape extending to the cylindrical inner wall and the cylindrical outer wall of the second storage node SN1 over the second dielectric layer DE1. The second storage node SN1 may be electrically connected to the horizontal conductive line LCL.

The second storage node SN1 may have a three-dimensional structure, and the second storage node SN1 of the three-dimensional structure may have a lateral three-dimensional structure which is oriented in the second direction D2. As an example of the three-dimensional structure, the second storage node SN1 may have a cylinder shape. According to another embodiment of the present invention, the second storage node SN1 may have a pillar shape or a pylinder shape. The pylinder shape may refer to a structure in which a pillar shape and a cylinder shape are merged.

The second storage node SN1 and the second plate node PN1 may include a metal, a noble metal, a metal nitride, a conductive metal oxide, a conductive noble metal oxide, a metal carbide, a metal silicide, or a combination thereof. For example, the second storage node SN1 and the second plate node PN1 may include titanium (Ti), titanium nitride (TiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, or a tungsten nitride/tungsten (WN/W) stack. The first plate node PN may include a combination of a metal or metal-based material and a silicon-based material. For example, the second plate node PN1 may be a stack of titanium nitride/silicon germanium/tungsten nitride (TIN/SiGe/WN). In the titanium nitride/silicon germanium/tungsten nitride (TiN/SiGe/WN) stack, silicon germanium may be a gap-fill material filling the cylindrical inside of the second storage node SN1 over the titanium nitride, and titanium nitride (TiN) may serve as a second plate node PN1 of a capacitor CAP, and tungsten nitride may be a low-resistance material.

The second dielectric layer DE1 may include silicon oxide, silicon nitride, a high-k material, or a combination thereof. The high-k material may have a higher dielectric constant than silicon oxide. Silicon oxide (SiO₂) may have a dielectric constant of approximately 3.9, and the second dielectric layer DE1 may include a high-k material having a dielectric constant of approximately 4 or more. The high-k material may have a dielectric constant of approximately 20 or more. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). According to another embodiment of the present invention, the second dielectric layer DE1 may be formed of a composite layer including two or more layers of the aforementioned high-k materials.

The second dielectric layer DE1 may be formed of zirconium (Zr)-based oxide. The second dielectric layer DE1 may have a stack structure including at least zirconium oxide (ZrO₂). The second dielectric layer DE1 may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked over zirconium oxide (ZrO₂). The ZAZ stack may have a structure in which zirconium oxide (ZrO₂), aluminum oxide (Al₂O₃), and zirconium oxide (ZrOz) are sequentially stacked. The ZA stack and the ZAZ stack may be referred to as a zirconium oxide (ZrO₂)-based layer. According to another embodiment of the present invention, the second dielectric layer DE1 may be formed of hafnium (Hf)-based oxide. The second dielectric layer DE1 may have a stack structure including at least hafnium oxide (HfO₂). The second dielectric layer DE1 may include an HA (HfO₂/Al₂O₃) stack or an HAH (HfO₂/Al₂O₃/HfO₂) stack. The HA stack may have a structure in which aluminum oxide (Al₂O₃) is stacked over hafnium oxide (HfO₂). The HAH stack may have a structure in which hafnium oxide (HfO₂), aluminum oxide (Al₂O₃), and hafnium oxide (HfO₂) are sequentially stacked. The HA stack and the HAH stack may be referred to as a hafnium oxide (HfO₂)-based layer. In the ZA stack, ZAZ stack, HA stack, and HAH stack, aluminum oxide (Al₂O₃) may have a greater bandgap energy (which will be, hereinafter, simply referred to as bandgap) than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the second dielectric layer DE1 may include a stack of a high-k material and a high-bandgap material having a greater bandgap than the high-k material. The second dielectric layer DE1 may include silicon oxide (SiO₂) as a high bandgap material other than aluminum oxide (Al₂O₃). Since the second dielectric layer DE1 includes a high bandgap material, leakage current may be suppressed. The high-bandgap material may be thinner than the high-k material. According to another embodiment of the present invention, the second dielectric layer DE1 may include a laminated structure in which a high-k material and a high-bandgap material are alternately stacked. For example, the second dielectric layer DE1 may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA (HfO₂/Al₂O₃/HfO₂/Al₂O₃) stack, or a HAHAH (HfO₂/Al₂O₃/HfO₂/Al₂O₃/HfO₂) stack. In the above laminated structure, aluminum oxide (Al₂O₃) may be thinner than zirconium oxide (ZrO₂) and hafnium oxide (HfO₂).

According to another embodiment of the present invention, the second dielectric layer DE1 may include a stack structure, a laminated structure, or a mixed structure including zirconium oxide, hafnium oxide, and aluminum oxide.

According to another embodiment of the present invention, the second dielectric layer DE1 may include a ferroelectric material or an antiferroelectric material. The ferroelectric material may include HfZrO, HfSiO, or a combination thereof. Each of the cell capacitors CAP and the reservoir capacitors RCAP may include a ferroelectric capacitor.

According to another embodiment of the present invention, an interface control layer for improving leakage current may be further formed between the second storage node SN1 and the second dielectric layer DE1. The interface control layer may include titanium oxide (TiO₂), niobium oxide, or niobium nitride. The interface control layer may also be formed between the first plate node PN and the second dielectric layer DE1.

The reservoir capacitor RCAP may include a metal-insulator-metal (MIM) capacitor. The second storage node SN1 and the second plate node PN1 may include a metal or metal-based material.

The second contact node CN2 may be formed between the second storage node SN1 and the second horizontal portion NL2. The second contact node CN2 may be coupled to the second horizontal portion NL2. The second contact node CN2 may include a conductive material. The second contact node CN2 may include a silicon-based material, a metal or metal-based material, or a combination thereof. The second contact node CN2 may include silicon, a metal, a metal nitride, a metal silicide, or a combination thereof. The second contact node CN2 may include polysilicon, titanium nitride, tungsten, or a combination thereof. For example, the second contact node CN2 may include N-type doped polysilicon or titanium nitride (TiN).

The semiconductor device 100 illustrated in FIGS. 1 to 3 may be a Dynamic Random Access Memory (DRAM) or a ferroelectric RAM (FERAM).

According to another embodiment of the present invention, the cell capacitors CAP and reservoir capacitor RCAP may be replaced by other data storage materials. For example, the data storage materials may be a phase-changing material, a Magnetic Tunnel Junction (MTJ) or variable resistive material.

One bit line BL may be in contact with the horizontal active layers ACT that are neighboring each other in the first direction D1. The horizontal active layers ACT that are neighboring each other in the third direction D3 may share the word line WL.

In the memory cell array MCA, a plurality of word lines WL may be vertically stacked in the first direction D1. Each of the word lines WL may include a pair of a first word line G1 and a second word line G2. A plurality of horizontal active layers ACT may be horizontally arranged to be spaced apart from each other in the third direction D3 between the first word line G1 and the second word line G2. According to another embodiment of the present invention, the word line WL may be replaced by a single word line structure of either the first word line G1 or the second word line G2 alone.

The lower structure LS may be a material appropriate for semiconductor processing. The lower structure LS may include at least one among a conductive material, a dielectric material, and a semiconductor material. The lower structure LS may include a semiconductor substrate, and the semiconductor substrate may be formed of a silicon-containing material. The lower structure LS may include semiconductor substrate 101 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The lower structure LS may also include another semiconductor material, such as germanium. The lower structure LS may include a III/V-group semiconductor substrate, for example, a compound semiconductor substrate, such as GaAs. The lower structure LS may include a Silicon-On-Insulator (SOI) substrate.

According to another embodiment of the present invention, the lower structure LS may include peripheral circuits. The peripheral circuits may include a plurality of peripheral circuit transistors. The peripheral circuits may be disposed at a lower level than the memory cell array MCA and the reservoir capacitor array CAR. This may be referred to as a COP (Cell-over-PERI) structure. The peripheral circuits may include at least one control circuit for driving the memory cell array MCA and the reservoir capacitor array CAR. The at least one control circuit of the peripheral circuits may include an N-channel transistor, a P-channel transistor, a CMOS circuit, or a combination thereof. The at least one control circuit of the peripheral circuit portion PERI may include an address decoder circuit, a read circuit, a write circuit, and the like. The at least one control circuit of the peripheral circuits may include a planar channel transistor, a recess channel transistor, a buried gate transistor, a fin channel transistor (FinFET), and the like.

For example, the peripheral circuits may include sub-word line drivers SWD, a sense amplifier SA, and a reservoir capacitor control circuit CL_RCAP. The word lines WL may be coupled to sub-word line drivers SWD. The bit lines BL may be coupled to the sense amplifier SA. The reservoir capacitors RCAP may be coupled to the reservoir capacitor control circuit CL_RCAP. The peripheral circuits may further include a control circuit coupled to the plate lines PL1 of the cell capacitors CAP.

According to another embodiment of the present invention, the lower structure LS may be disposed at a higher level than the memory cell array MCA and the reservoir capacitor array CAR. This may be referred to as a PUC (PERI-over-Cell) structure. In the PUC structure, the peripheral circuits may be disposed at a higher level than the memory cell array MCA and the reservoir capacitor array CAR.

According to another embodiment of the present invention, the lower structure LS may be referred to as a first peripheral circuit portion, and the reservoir capacitor array CAR may be referred to as a second peripheral circuit portion. Accordingly, the first peripheral circuit portion may be disposed at a lower level than the memory cell array MCA, and the second peripheral circuit portion may be disposed horizontally from the memory cell array MCA. The first peripheral circuit portion may include control circuits such as a sense amplifier and a sub-word line driver for controlling the memory cell array MCA. The second peripheral circuit portion may include a reservoir capacitor array CAR, and the control circuits for controlling the reservoir capacitor array CAR may be disposed in the first peripheral circuit portion.

The constituent elements of the cell capacitors CAP and the constituent elements of the reservoir capacitors RCAP may be formed of the same shape and the same material. For example, the storage nodes SN of the cell capacitors CAP and the storage nodes SN1 of the reservoir capacitors RCAP may have a cylindrical shape.

The bit line BL of the memory cell array MCA and the vertical conductive line VCL of the reservoir capacitor array CAR may be formed of the same material.

The bit line contact node BLC of the memory cell array MCA and the first contact node CN1 of the reservoir capacitor array CAR may have the same shape and the same material.

The storage contact node SNC of the memory cell array MCA and the second contact node CN2 of the reservoir capacitor array CAR may have the same shape and the same material.

The first and second source/drain regions DR and SR of the memory cell array MCA and the first and second horizontal portions NL1 and NL2 of the reservoir capacitor array CAR may be doped with the same impurity.

The constituent elements of the memory cell array MCA and the reservoir capacitor array CAR may be similar except for the word line WL. The memory cell array MCA may include a word line WL, and the reservoir capacitor array CAR may be word line-free.

According to the embodiment of the present invention described above, a bias such as VPP may be stabilized by forming the reservoir capacitors RCAP.

Also, since the reservoir capacitor array of a three-dimensional array is formed horizontally from the memory cell array in the same structure as that of the cell capacitors of the memory cell array, the capacitance of the reservoir capacitors can be increased by securing the area of the reservoir capacitors.

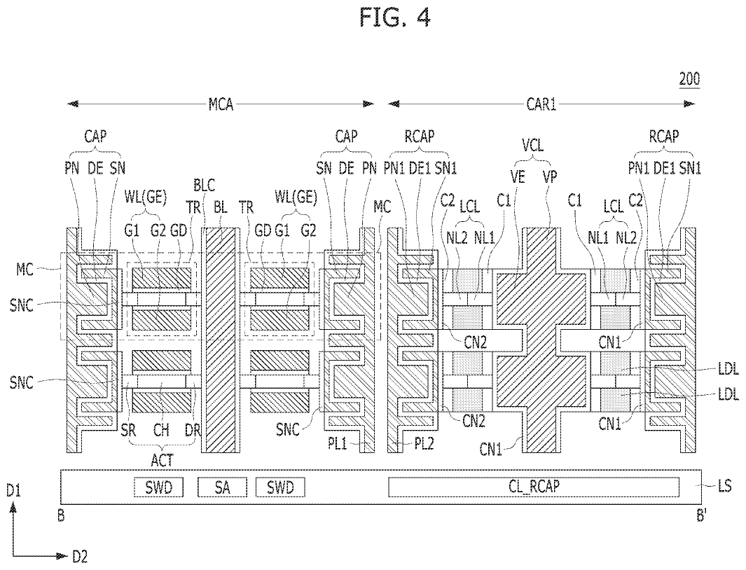

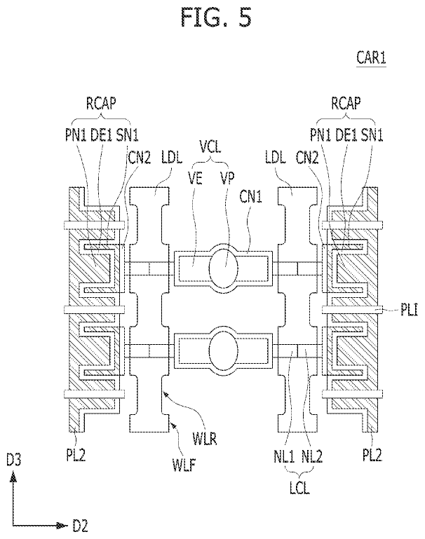

FIGS. 4 and 5 illustrate a semiconductor device in accordance with another embodiment of the present invention. FIG. 4 is a cross-sectional view of a semiconductor device 200, and FIG. 5 is a plan view of a reservoir capacitor array CAR1 of the semiconductor device 200. The semiconductor device 200 shown in FIGS. 4 and 5 may be similar to the semiconductor device 100 shown in FIGS. 1 to 3. Hereinafter, as for the detailed descriptions on the constituent elements, FIGS. 1 to 3 may be referred to.

The semiconductor device 200 may include a memory cell array MCA as illustrated in FIGS. 1 to 3, and the semiconductor device 200 may further include a reservoir capacitor array CAR1. The reservoir capacitor array CAR1 may include a horizontal conductive line LCL, a reservoir capacitor RCAP, and a vertical conductive line VCL. The reservoir capacitor array CAR1 may further include a lateral dielectric line LDL. The lateral dielectric line LDL may extend in the third direction D3 crossing the horizontal conductive line LCL.

The reservoir capacitor array CAR1 may be another embodiment that may replace the reservoir capacitor array CAR shown in FIG. 2. The reservoir capacitor array CAR shown in FIG. 2 may not include the lateral dielectric line LDL, and the reservoir capacitor array CAR1 shown in FIGS. 4 and 5 may include the lateral dielectric line LDL.

The lateral dielectric line LDL may include a dielectric material. For example, the lateral dielectric line LDL may include silicon oxide, silicon nitride, or a combination thereof. The lateral dielectric line LDL may be a non-conductive material and may not have an electrical effect on the horizontal conductive line LCL.

The lateral dielectric line LDL may have the same shape as that of the word line WL of the memory cell array MCA. For example, the lateral dielectric line LDL may include notch-shaped sidewalls, and the notch-shaped sidewalls may include flat surfaces WLF and recessed surfaces WLR, individually.

The lateral dielectric line LDL may directly contact the horizontal conductive line LCL. The lateral dielectric line LDL may not contact the first contact node CN1 and the second contact node CN2.

A first capping layer C1 and a second capping layer C2 may be formed on both sides of the lateral dielectric lines LDL, respectively. The first capping layer C1 and the second capping layer C2 may include a dielectric material. For example, the first capping layer C1 and the second capping layer C2 may include silicon oxide, silicon nitride, or a combination thereof.

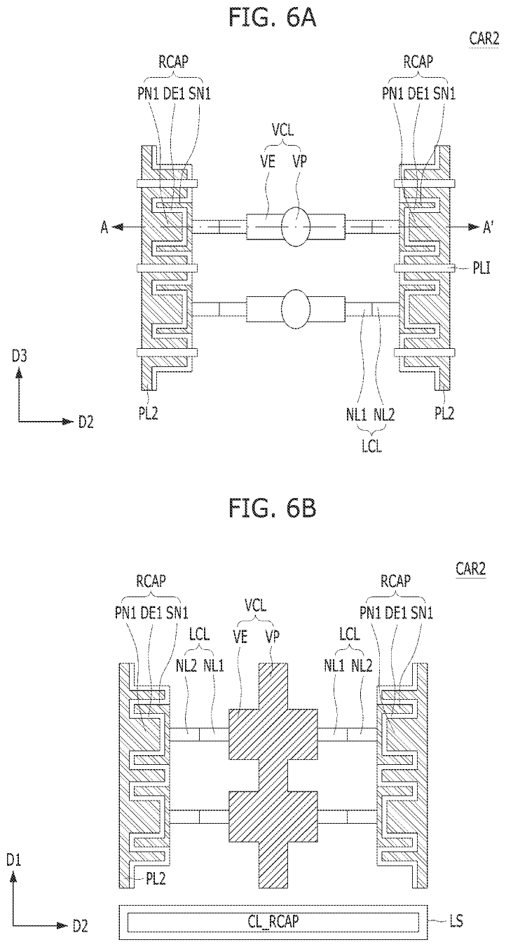

FIG. 6A is a plan view illustrating a reservoir capacitor array CAR2 in accordance with another embodiment of the present invention. FIG. 6B is a cross-sectional view taken along a line A-A′ of FIG. 6A. The reservoir capacitor array CAR2 shown in FIGS. 6A and 6B may be similar to the reservoir capacitor arrays CAR and CAR1 shown in FIGS. 1 to 5. Hereinafter, as for the detailed descriptions on the constituent elements, FIGS. 1 to 5 may be referred to.

The reservoir capacitor array CAR2 may include a horizontal conductive line LCL, a reservoir capacitor RCAP, and a vertical conductive line VCL.

In an embodiment, the reservoir capacitor array CAR2 may replace the reservoir capacitor array CAR of FIGS. 2 and 3. Whereas the reservoir capacitor array CAR of FIGS. 2 and 3 includes first and second contact nodes CN1 and CN2, the first and second contact nodes CN1 and CN2 may be omitted in the reservoir capacitor array CAR2 of FIGS. 6A and 6B.

The storage node SN1 of the reservoir capacitor RCAP may directly contact the second horizontal portion NL2 of the horizontal conductive line LCL.

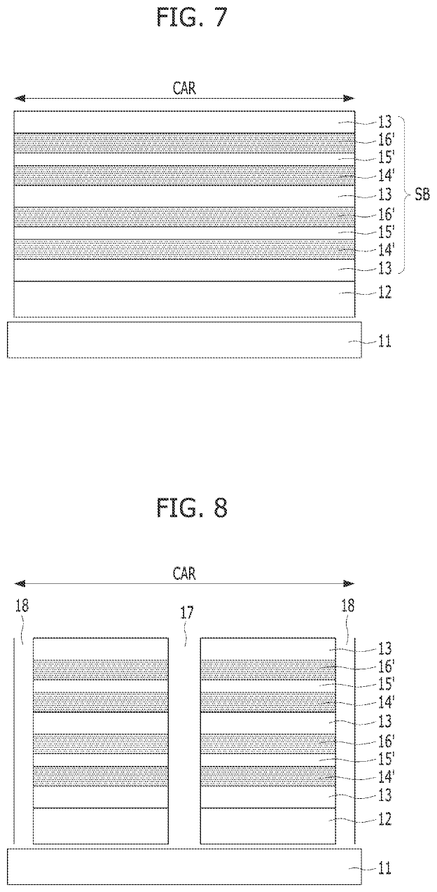

FIGS. 7 to 21 are diagrams illustrating a method for fabricating a semiconductor device in accordance with an embodiment of the present invention. FIGS. 7 to 21 illustrate a method for forming the reservoir capacitor array CAR which is described by referring to FIGS. 1 to 3.

Referring to FIG. 7, an inter-layer dielectric layer 12 may be formed over the lower structure 11, and the stack body SB may be formed over the inter-layer dielectric layer 12. The stack body SB may be formed by repeatedly forming a sub-stack in which a dielectric layer 13, a first sacrificial layer 14′, a semiconductor layer 15′, and a second sacrificial layer 16′ are stacked in the mentioned order. The dielectric layer 13 may be silicon oxide, and the first and second sacrificial layers 14′ and 16′ may be silicon nitride. The semiconductor layer 15′ may include a silicon layer, a monocrystalline silicon layer, or a polysilicon layer. In the stack body SB, the uppermost layer may be the dielectric layer 13. According to another embodiment of the present invention, the semiconductor layer 15′ may include an oxide semiconductor material.

The lower structure 11 may include a semiconductor substrate or peripheral circuits. The inter-layer dielectric layer 12 may include silicon oxide, silicon nitride, or a combination thereof.

Referring to FIG. 8, a plurality of openings 17 and 18 may be formed in the stack body SB. The openings 17 and 18 may have a hole shape. The openings 17 and 18 may be formed by etching the stack body SB and then subsequently etching the inter-layer dielectric layer 12 to expose the lower structure 11. The openings 17 and 18 may include a first opening 17 and a second opening 18. The first opening 17 and the second opening 18 may have the same cross-sectional size. The first opening 17 and the second opening 18 may have different cross-sectional sizes.

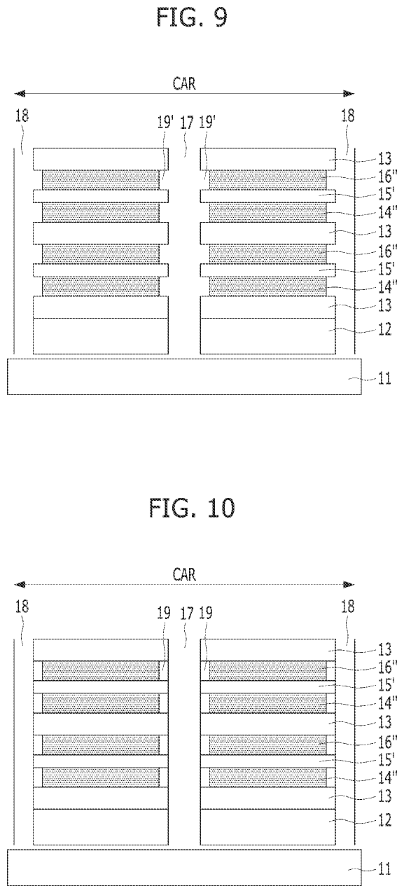

Referring to FIG. 9, the first and second sacrificial layers 14′ and 16′ may be partially recessed through the first and second openings 17 and 18. For example, partial etching of the first and second sacrificial layers 14′ and 16′ may be performed to form first and second sacrificial layer patterns 14″ and 16″. Sacrificial recesses 19′ may be formed on both sides of the first and second sacrificial layer patterns 14″ and 16″.

The sacrificial recesses 19′ may exposed some surfaces (e.g., both ends) of the semiconductor layers 15′. The sacrificial recesses 19′ may be formed between the dielectric layers 13 and the semiconductor layers 15′.

Referring to FIG. 10, sacrificial cap layers 19 filling the sacrificial recesses 19′ may be formed. The sacrificial cap layers 19 may be formed of the same material as those of the first and second sacrificial layer patterns 14″ and 16″. The sacrificial cap layers 19 may be silicon nitride. The sacrificial cap layers 19 may not fill the first and second openings 17 and 18.

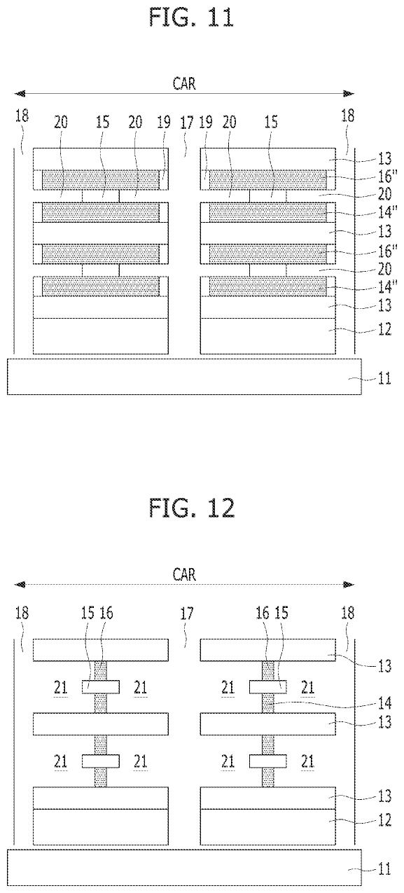

Referring to FIG. 11, the semiconductor layers 15′ may be horizontally recessed through the first and second openings 17 and 18. As a result, semiconductor layer patterns 15 may be formed, and lateral recesses 20 may be formed on both sides of the semiconductor layer patterns 15. During the formation of the semiconductor layer patterns 15, the sacrificial cap layers 19 and the first and second sacrificial layer patterns 14″ and 16″ may not be lost.

Referring to FIG. 12, expanded lateral recesses 21 may be formed. The expanded lateral recesses 21 may be formed by partially etching the sacrificial cap layers 19 and the first and second sacrificial layer patterns 14″ and 16″. While the sacrificial cap layers 19 and the first and second sacrificial layer patterns 14″ and 16″ are being etched, the dielectric layers 13 may not be etched. First and second lateral dielectric lines 14 and 16 may be formed in the upper and lower portions of the semiconductor layer patterns 15 by the partial etching of the first and second sacrificial layer patterns 14″ and 16″, respectively. The lateral lengths of the first and second lateral dielectric lines 14 and 16 may be smaller than the lateral lengths of the semiconductor layer patterns 15. The first and second lateral dielectric lines 14 and 16 may expose portions (e.g., both ends) of the semiconductor layer patterns 15.

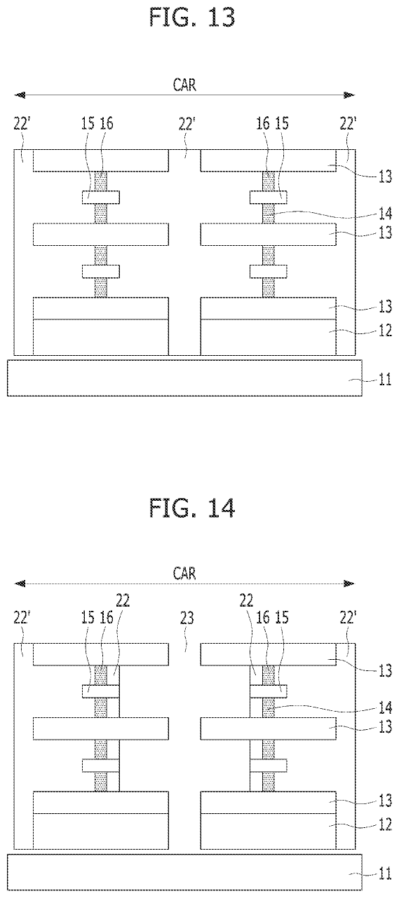

Referring to FIG. 13, an isolation layer 22′ may fill expanded lateral recesses 21 and the first and second openings 17 and 18. The isolation layer 22′ may include silicon oxide, silicon nitride, or a combination thereof. The isolation layer 22′ may include an Oxide-Nitride-Oxide (ONO) structure. The isolation layer 22′ may include a silicon oxide liner, a silicon nitride liner, and silicon oxide that are stacked in the mentioned order. For example, after a silicon oxide liner and a silicon nitride liner are sequentially deposited over the expanded lateral recesses 21, a silicon oxide may be deposited to fill the expanded lateral recesses 21 over the silicon nitride liner. A surface oxidation process of the semiconductor layer patterns 15 may be performed prior to the process of depositing the silicon oxide liner. Subsequently, the isolation layer 22′ may be planarized to expose the surface of the uppermost dielectric layer 13.

Referring to FIG. 14, a portion of the isolation layer 22′ may be etched to form a third opening 23. The third opening 23 may expose first sides of the horizontally neighboring semiconductor layer patterns 15. The third opening 23 may be formed by sequentially exposing portions of the isolation layer 22′ to a dry etching process and a wet etching process. As the third opening 23 is formed, first capping layers 22 may be formed. The first capping layers 22 may be disposed in the upper and lower portions of first portions of the semiconductor layer patterns 15. The first portions of the semiconductor layer patterns 15 may include first sides that are exposed by the third opening 23. The first capping layers 22 may be a portion of the isolation layer 22′.

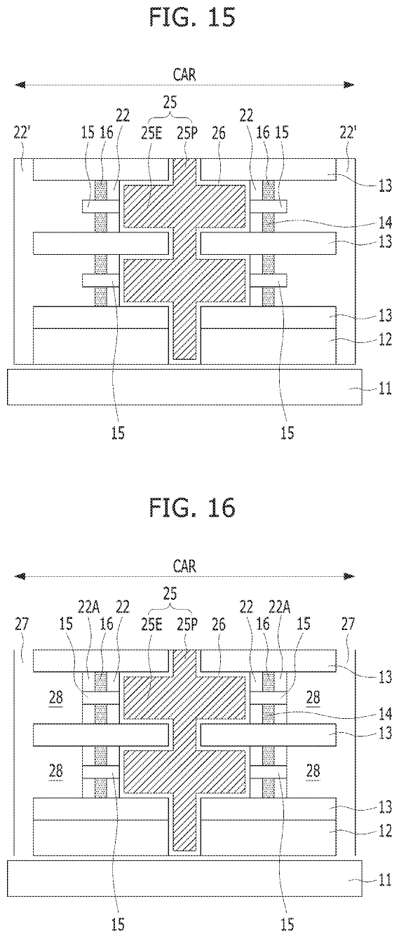

Referring to FIG. 15, a vertical conductive line 25 filling the third opening 23 may be formed. Before the vertical conductive line 25 is formed, a first contact node 26 may be formed. The first contact node 26 may be conformally formed over the third opening 23 and the first capping layers 22. The vertical conductive line 25 may be formed by depositing a conductive material over the first contact node 26 to fill the third opening 23 and then planarizing the conductive material. The first contact node 26 and the vertical conductive line 25 may be commonly coupled to the first portions of the semiconductor layer patterns 15. First capping layers 22 may be disposed between the first contact node 26 and the lateral dielectric lines 15 and 16. The vertical conductive line 25 may include a pillar portion 25P and extended portions 25E extending horizontally from the pillar portion 25P.

The first contact node 26 may include a semiconductor material, and the vertical conductive line 25 may include a metal or metal-based material. The first contact node 26 may include polysilicon which is doped with an N-type impurity. The vertical conductive line 25 may include tungsten, titanium nitride, or a combination thereof.

Referring to FIG. 16, a portion of the remaining isolation layer 22′ may be etched to form a fourth opening 27 and fifth openings 28. A portion of the isolation layer 22′ may be vertically etched to form the fourth opening 27, and the isolation layer 22′ may be horizontally recessed from the fourth opening 27 to form the fifth openings 28. The fifth openings 28 may be portions extending horizontally from the fourth opening 27.

The fifth openings 28 may expose second sides of the semiconductor layer patterns 15. To form the fourth and fifth openings 27 and 28, a portion of the isolation layer 22′ may be sequentially exposed to a dry etching process and a wet etching process. As a result of forming the fifth openings 28, second capping layers 22A may be formed. The second capping layers 22A may be disposed in the upper and lower portions of the second portions of the semiconductor layer patterns 15. The second portions of the semiconductor layer patterns 15 may include second sides that are exposed by the fifth openings 28. The second capping layers 22A may be of the same material as that of the isolation layer 22′.

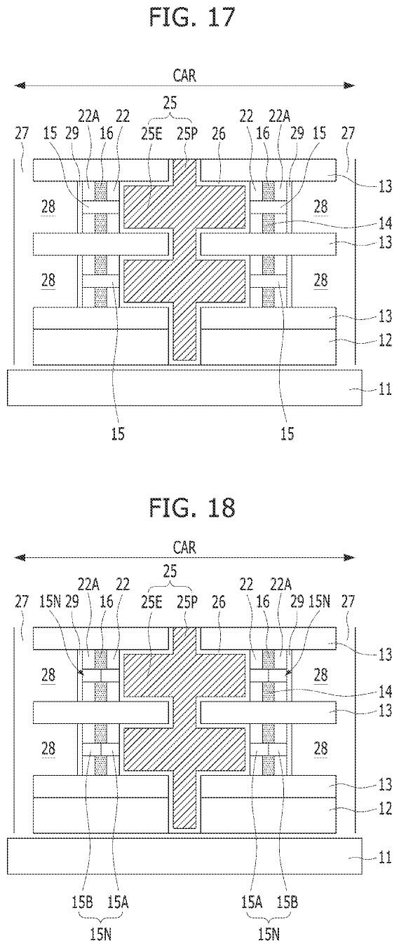

Referring to FIG. 17, second contact nodes 29 may be formed on the sides of the second capping layers 22A. The second contact nodes 29 may be respectively formed on the other sides of the semiconductor layer patterns 15. The second contact nodes 29 may be formed to be separated from each other by the dielectric layer 13. Each of the second contact nodes 29 may have a vertical sidewall shape which is formed on the other sides of the semiconductor layer patterns 15 and the side of the second capping layers 22A. The second contact nodes 29 may include polysilicon which is doped with an N-type impurity.

Referring to FIG. 18, the semiconductor layer patterns 15 may be replaced with horizontal conductive lines 15N. The horizontal conductive lines 15 may be doped with an impurity. For example, the horizontal conductive lines 15N may be doped with impurities that are diffused from the first and second contact nodes 26 and 29. The horizontal conductive lines 15N may include a first doped region 15A and a second doped region 15B. The first doped region 15A may include an impurity diffused from the first contact node 26, and the second doped region 15B may include an impurity diffused from the second contact node 29. The semiconductor layer patterns 15 may be exposed to a thermal process to form the horizontal conductive lines 15N. Herein, the thermal process may be performed at a temperature capable of diffusing impurities from the first and second contact nodes 26 and 29. The lateral diffusion lengths of the first doped region 15A and the second doped region 15B may be the same. When the first and second contact nodes 26 and 29 include polysilicon doped with an N-type impurity, the first doped region 15A and the second doped region 15B may be regions doped with N-type impurities.

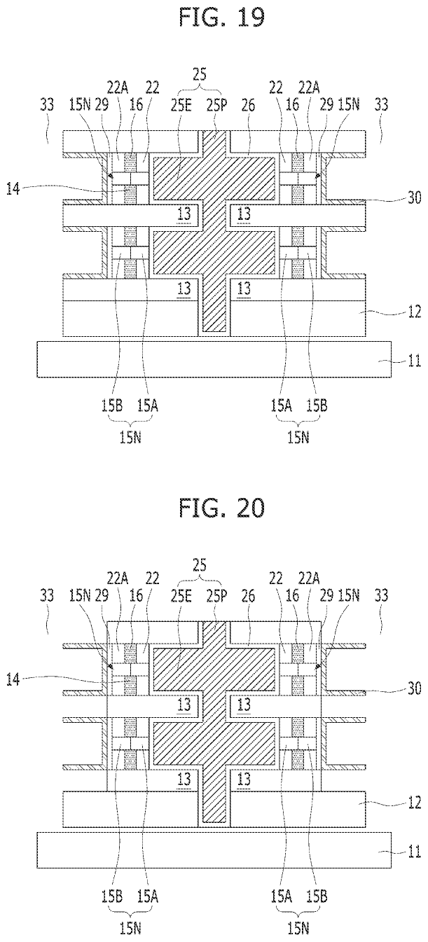

Referring to FIGS. 19 to 21, reservoir capacitors RCAP may be formed in the fourth and fifth openings 27 and 28. Each of the reservoir capacitors RCAP may include a storage node 30, a dielectric layer 31, and a plate node 32. Each of the storage nodes 30 may be coupled to the second contact node 29. The plate nodes 32 may be coupled to each other and coupled to the plate line 33. The plate line 33 and the plate nodes 32 may be integrated.

First of all, referring to FIG. 19, the storage node 30 may be formed in the fifth openings 28. The storage node 30 may be formed by depositing and etching a conductive material.

Referring to FIG. 20, the dielectric layers 31 may be horizontally recessed to expose the outer walls of the storage node 30.

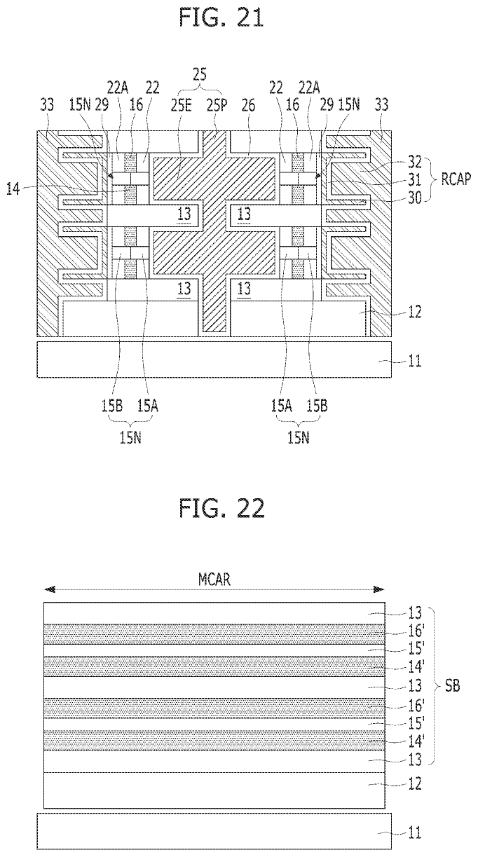

Referring to FIG. 21, a dielectric layer 31 and a plate node 32 may be sequentially formed on the storage node 30.

While the reservoir capacitors RCAP as illustrated in FIGS. 7 to 21 are formed, a three-dimensional array of cell capacitors may be simultaneously formed. For example, both of the memory cell array and the reservoir capacitor array may be simultaneously formed over the lower structure 11. The reservoir capacitors RCAP may have the same structure as those of the cell capacitors, and the reservoir capacitors RCAP may be formed at the same level as those of the cell capacitors and have the same size. Whereas the memory cell array may form the word line WL, the reservoir capacitor array may form the lateral dielectric lines 14 and 16.

FIGS. 22 to 30 illustrate a method for fabricating a memory cell array. FIGS. 22 to 30 illustrate a method for forming the memory cell array MCA which is illustrated in FIGS. 1 to 3.

Referring to FIG. 22, an inter-layer dielectric layer 12 may be formed over the lower structure 11, and a stack body SB may be formed over the inter-layer dielectric layer 12. The stack body SB may be formed by repeatedly forming a sub-stack in which a dielectric layer 13, a first sacrificial layer 14′, a semiconductor layer 15′, and a second sacrificial layer 16′ are stacked in the mentioned order. The dielectric layer 13 may be silicon oxide, and the first and second sacrificial layers 14′ and 16′ may be silicon nitride. The semiconductor layer 15′ may include a silicon layer, a monocrystalline silicon layer, or a polysilicon layer. In the stack body SB, the uppermost layer may be a dielectric layer 13. According to another embodiment of the present invention, the semiconductor layer 15′ may include an oxide semiconductor material.

The lower structure 11 may include a semiconductor substrate or peripheral circuits. The inter-layer dielectric layer 12 may include silicon oxide, silicon nitride, or a combination thereof.

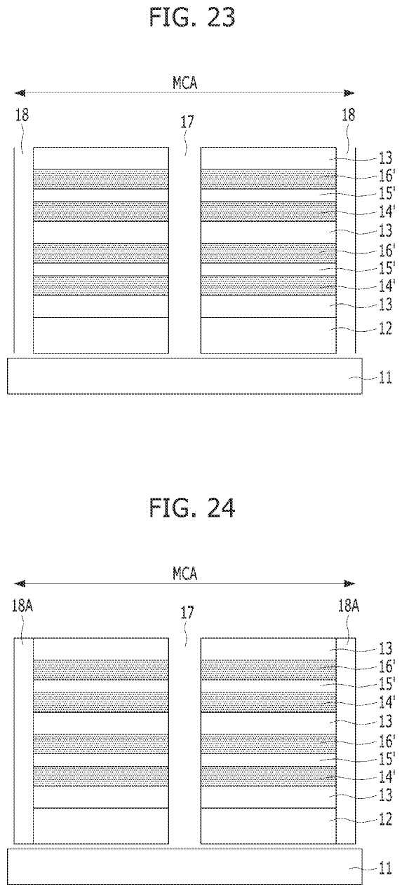

Referring to FIG. 23, a plurality of openings 17 and 18 may be formed in the stack body SB. The openings 17 and 18 may have a hole shape. The openings 17 and 18 may be formed by etching the stack body SB and then etching the inter-layer dielectric layer 12 subsequently. The openings 17 and 18 may include a first opening 17 and a second opening 18. The first opening 17 and the second opening 18 may have the same size or different sizes.

Referring to FIG. 24, vertical sacrificial layers 18A filling the second openings 18 may be formed. The vertical sacrificial layers 18A may include silicon oxide, silicon nitride, or a combination thereof.

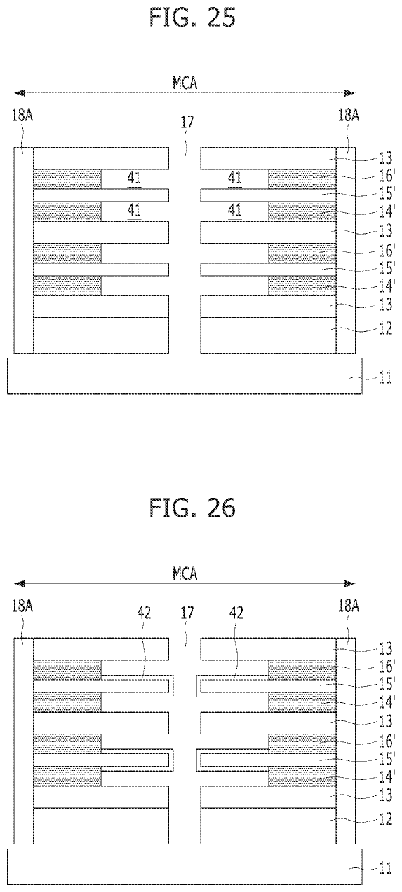

Referring to FIG. 25, the first and second sacrificial layers 14′ and 16′ may be partially recessed through the first opening 17. For example, the first and second sacrificial layers 14′ and 16′ may be partially etched. Gate recesses 41 may be formed as a result of partially etching the first and second sacrificial layers 14′ and 16′. The gate recesses 41 may expose some surfaces of the semiconductor layers 15′. The gate recesses 41 may be formed between the dielectric layers 13 and the semiconductor layers 15′.

Referring to FIG. 26, the exposed surfaces of the semiconductor layers 15′ that are exposed by the gate recesses 41 may be selectively oxidized to form gate dielectric layers 42 on exposed surfaces of the semiconductor layers 15′. The gate dielectric layers 42 may include silicon oxide.

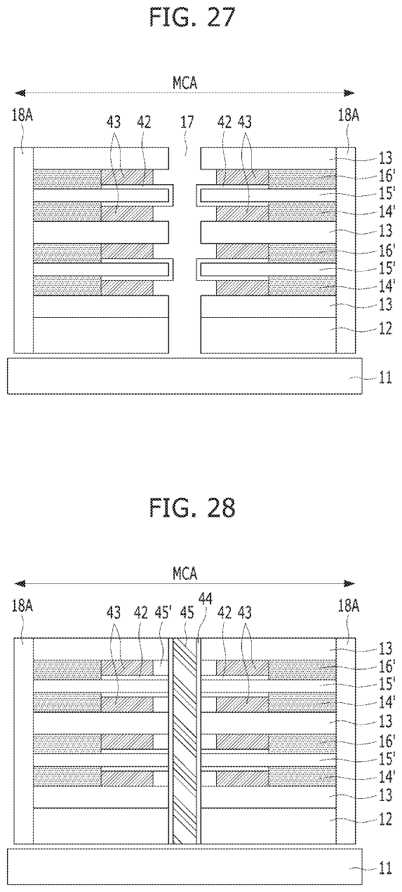

Referring to FIG. 27, a double word line 43 filling the gate recesses 41 may be formed over the gate dielectric layers 42. The double word line 43 may be formed by first depositing and then etching a conductive material.

Referring to FIG. 28, a bit line side cap layer 45′ may fill the side of the double word line 43.

Subsequently, a bit line 45 may be formed to fill the first opening 17. Before the bit line 45 is formed, a bit line contact node 44 may be formed. The bit line contact node 44 may include a semiconductor material, and the bit line 45 may include a metal or metal-based material. The bit line contact node 44 may include polysilicon which is doped with an N-type impurity. The bit line 45 may include tungsten, titanium nitride, or a combination thereof.

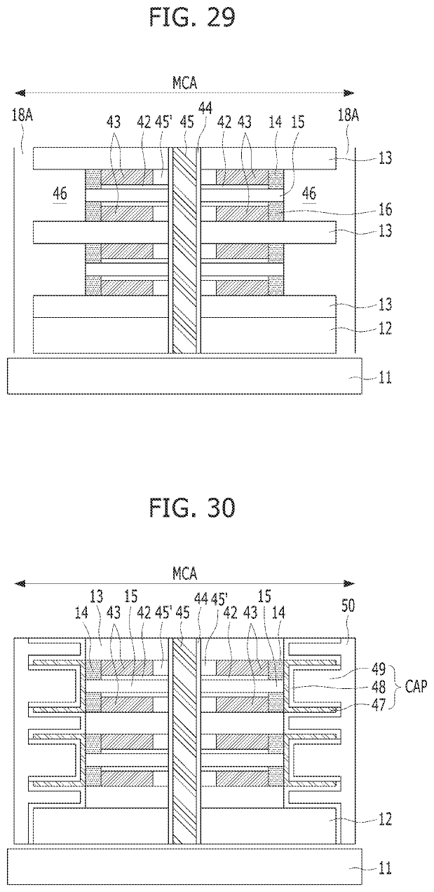

Referring to FIG. 29, the vertical sacrificial layers 18A are removed and capacitor openings 46 are formed. The capacitor openings 46 may be formed by horizontally recessing portions of the first and second sacrificial layers 14 and 16 and the semiconductor layers 15′.

As the capacitor openings 46 are formed, the semiconductor layer 15′ may remain as the horizontal active layer 15, and the first and second sacrificial layers 14′ and 16′ may remain as the capacitor-side capping layer 14 and 16.

Referring to FIG. 30, cell capacitors CAP may be formed in the capacitor openings 46. Each of the cell capacitors CAP may include a storage node 47, a dielectric layer 48, and a plate node 49. The plate nodes 49 may be coupled to each other and coupled to the plate line 50. The plate line 50 and the plate nodes 49 may be integrated.

A method for forming the cell capacitors CAP may be similar to the method for forming the reservoir capacitors RCAP illustrated in FIGS. 16 to 21. The cell capacitors CAP and the reservoir capacitors RCAP may be formed simultaneously.

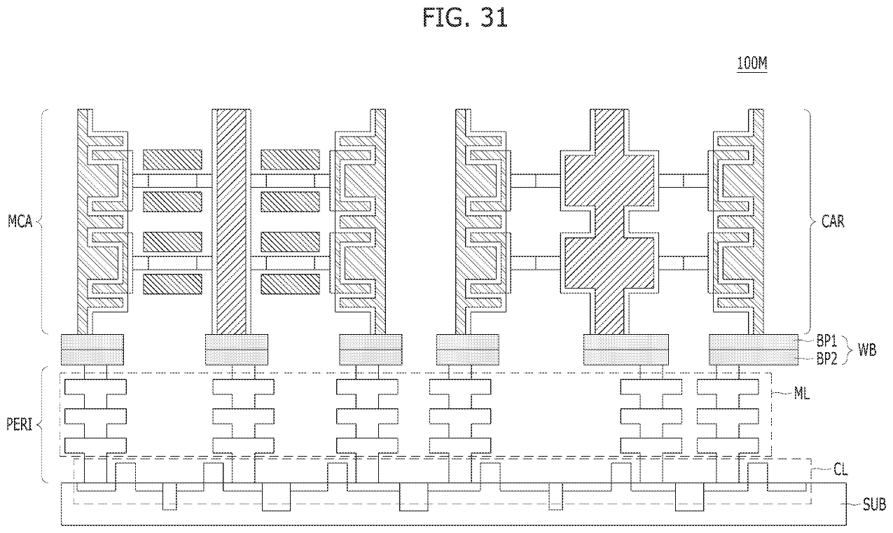

FIG. 31 is a schematic cross-sectional view illustrating a semiconductor device in accordance with another embodiment of the present invention. The semiconductor device 100M of FIG. 31 may be similar to the semiconductor device 100 of FIG. 3.

Referring to FIG. 31, the semiconductor device 100M may include a peripheral circuit portion PERI, a memory cell array MCA, and a reservoir capacitor array CAR. The memory cell array MCA and the reservoir capacitor array CAR may be disposed over the peripheral circuit portion PERI. The memory cell array MCA and the peripheral circuit portion PERI may be coupled by wafer bonding. The semiconductor device 400 may have a COP (Cell Over Peri) structure. The reservoir capacitor array CAR and the peripheral circuit portion PERI may be coupled by wafer bonding.

As for the detailed description on the memory cell array MCA and the reservoir capacitor array CAR, FIG. 3 may be referred to.

A bonding structure WB may be disposed between the peripheral circuit portion PERI and the memory cell array MCA. The bonding structure WB may include first and second bonding pads BP1 and BP2. The memory cell array MCA and the peripheral circuit portion PERI may be coupled to each other by metal-to-metal bonding or hybrid bonding. For example, they may be coupled to each other through the first and second bonding pads BP1 and BP2. Metal-to-metal bonding may refer to direct bonding between the first bonding pads BP1 and the second bonding pads BP2, and hybrid bonding may refer to a combination of metal-to-metal bonding and dielectric bonding. The first and second bonding pads BP1 and BP2 may include a metal material.

Referring to FIGS. 1 and 31, the bit line BL and the plate line PL of the memory cell array MCA may be respectively coupled to the first bonding pads BP1.

The peripheral circuit portion PERI may include a plurality of control circuits CL and a plurality of interconnections ML that are formed over a substrate SUB. For example, the control circuits CL of the peripheral circuit portion PERI may include a sense amplifier, a sub-word line driver, and a plate line control circuit. The sense amplifier may be coupled to the bit line BL through the interconnection ML. The sub-word line driver may be coupled to the word lines WL through the interconnection ML. The plate line control circuit may be connected to the plate line PL through the interconnection ML. The second bonding pads BP2 may be coupled to the interconnections ML.

The bit line BL, the cell capacitors CAP, and the word lines WL of the memory cell array MCA may be electrically connected to the control circuits CL of the peripheral circuit portion PERI through a bonding structure WB.

The vertical conductive line VCL and the reservoir capacitors RCAP of the reservoir capacitor array CAR may be electrically connected to the control circuits CL of and the peripheral circuit portion PERI through the bonding structure WB.

According to another embodiment of the present invention, the semiconductor device 100M may have a POC (Peri-Over-Cell) structure. The POC structure may refer to a structure in which a peripheral circuit portion PERI is disposed over the memory cell array MCA and the reservoir capacitor array CAR.

According to another embodiment of the present invention, the reservoir capacitor array CAR of the semiconductor device 100M may be replaced by the reservoir capacitor arrays CAR1 and CAR2 shown in FIGS. 4 to 6B.

According to the embodiment of the present invention, since a reservoir capacitor array which is arranged horizontally with respect to a memory cell array is formed, a bias such as VPP may be stabilized.

According to the embodiment of the present invention, since a three-dimensional reservoir capacitor array is formed horizontally with respect to the memory cell array in the same structure as those of the cell capacitors of a three-dimensional memory cell array, it is possible to increase the capacitance of the reservoir capacitors by securing the area for the reservoir capacitors.

While the present invention has been described with respect to specific embodiments, it will be apparent to those skilled in the art that various changes and modifications may be made without departing from the spirit and scope of the invention as defined in the following claims.

What is claimed is:

1. A semiconductor device, comprising:
a lower structure;
a plurality of horizontal conductive layers that are oriented horizontally in a direction parallel to a surface of the lower structure;
a vertical conductive line commonly coupled to first-side ends of the horizontal conductive layers and extending in a direction perpendicular to the surface of the lower structure; and
a plurality of reservoir capacitors respectively coupled to second-side ends of the horizontal conductive layers and vertically stacked over the lower structure.

2. The semiconductor device of claim 1, wherein each of the reservoir capacitors includes:
storage nodes respectively coupled to the second-side ends of the horizontal conductive lines;
a dielectric layer suitable for covering the storage nodes; and
a plate node over the dielectric layer.

3. The semiconductor device of claim 2, further comprising:
a plate line which is vertically oriented in a direction perpendicular to the surface of the lower structure,
wherein the plate nodes of the reservoir capacitors are coupled to the plate line.

4. The semiconductor device of claim 1, wherein the horizontal conductive lines include a semiconductor material, a doped semiconductor material, an oxide semiconductor material, or a metal or metal-based material.

5. The semiconductor device of claim 1, wherein the lateral conductive lines include a doped silicon material which is doped with an N-type impurity.

6. The semiconductor device of claim 1, wherein the vertical conductive line includes a silicon-based material, a metal or metal-based material, or a combination thereof.

7. The semiconductor device of claim 1, further comprising:
a first contact node disposed between the horizontal conductive lines and the vertical conductive line and surrounding an outer wall of the vertical conductive line; and
a second contact node disposed between the horizontal conductive lines and the reservoir capacitors, the second contact node being vertically oriented.

8. The semiconductor device of claim 7, wherein the first contact node and the second contact node include a doped polysilicon layer which is doped with an N-type impurity.

9. The semiconductor device of claim 1, wherein the vertical conductive line includes:
a pillar portion which is oriented vertically in a direction perpendicular to the surface of the lower structure; and
extended portions extending horizontally from the pillar portion.

10. The semiconductor device of claim 1, wherein the lower structure includes a control circuit suitable for controlling the reservoir capacitors.

11. The semiconductor device of claim 1, further comprising:
a memory cell array which is disposed over the lower structure and arranged horizontally from the reservoir capacitors.

12. The semiconductor device of claim 11, wherein the memory cell array includes a plurality of cell capacitors that are vertically stacked over the lower structure, and the cell capacitors have the same structure as the reservoir capacitors.

13. The semiconductor device of claim 12, wherein the reservoir capacitors are formed at the same level as the cell capacitors and have the same size.

14. The semiconductor device of claim 12, wherein the memory cell array further includes:
horizontal active layers extending in a direction parallel to the surface of the lower structure;
a bit line commonly coupled to first sides of the horizontal active layers and extending in a direction perpendicular to the surface of the lower structure; and
word lines respectively overlapping with the horizontal active layers and extending in a direction crossing the horizontal active layers, and
wherein the cell capacitors are respectively coupled to second sides of the horizontal active layers.

15. The semiconductor device of claim 14, wherein each of the word lines includes notch-shaped sidewalls.

16. The semiconductor device of claim 14, wherein each of the word lines includes double word lines that are facing each other with the horizontal active layer interposed therebetween.

17. The semiconductor device of claim 14, wherein each of the horizontal active layers includes a monocrystalline semiconductor material, a polycrystalline semiconductor material, an oxide semiconductor material, a nanowire, or a nanosheet.

18. The semiconductor device of claim 11, wherein the memory cell array includes a DRAM memory cell array.

19. The semiconductor device of claim 11, further comprising:
peripheral circuits disposed at a lower level or a higher level than the memory cell array and the reservoir capacitors.
